(19) United States
(12) Patent Application Publication
(10) Pub. No.: US 2007/0141752 A1
(43) Pub. Date: Jun. 21, 2007

(54) MANUFACTURING METHOD OF SEMICONDUCTOR INTEGRATED CIRCUIT DEVICE

(76) Inventors: Yoshiyuki Abe, Tokyo (JP); Chuichi Miyazaki, Tokyo (JP)

Correspondence Address: MATTINGLY, STANGER, MALUR & BRUNDIDGE, P.C., 1800 DIAGONAL ROAD, SUITE 370, ALEXANDRIA, VA, 22314, US

(21) Appl. No.: 11/610,764

(22) Filed: Dec. 14, 2006

(30) Foreign Application Priority Data
Dec. 15, 2005 (JP) 2005-361850

(51) Int. Cl. H01L 21/00; H01L 21/461

(52) U.S. Cl. 438/113; 438/692; 257/E21.23

(57) ABSTRACT

The lowering of the manufacturing yield of semiconductor products resulting from the contamination impurities from the back surface of a semiconductor wafer is suppressed.

When making thin semiconductor wafer 1, the first crushing layer formed by grinding the back surface of semiconductor wafer 1 with the first and second abrasive which has fixed abrasive is removed. Thereby, the die strength after dividing or mostly dividing semiconductor wafer 1 and making a chip is secured. Then, from the back surface side of semiconductor wafer 1, laser beam 16 is irradiated in the predetermined region of the predetermined depth from the back surface of semiconductor wafer 1, and for example, second crushing layer 15 with the gettering function of less than 1.0 μm, less than 0.5 μm, or less than 0.1 μm in thickness is formed newly.

### CROSS-REFERENCE TO RELATED APPLICATION

The present application claims priority from Japanese patent application No. 2005-361850 filed on Dec. 15, 2005, the content of which is hereby incorporated by reference into this application.

1. Field of the Invention

The present invention relates to the manufacturing technology of a semiconductor integrated circuit device, and particularly relates to an effective technology in the application to manufacture of the semiconductor integrated circuit device to dicing which carves a semiconductor wafer into an each semiconductor chip (only henceforth a chip) from the back-grinding which grinds the back surface of a semiconductor wafer after formation of a circuit pattern is mostly completed on a semiconductor wafer, and die bonding which a chip is picked up further and mounted in a substrate.

2. Description of the Background Art

The technology in which the improvement in the yield of semiconductor products and shortening of TAT are realizable is disclosed (for example, refer to Patent Reference 1), by, for example removing the contamination impurities which invaded from the back surface of a semiconductor wafer, forming an oxide film in a back surface and setting it as the barrier of diffusion of contamination impurities, and forming a damaged layer and improving the gettering effect etc.

The wafer processing method which grinds the wafer back surface where a plurality of semiconductor elements were formed in the front surface, polishes the grinding surface formed of the grinding action, and forms an oxide film in a polish performing plasma treatment to the polish formed of scouring under a predetermined gas atmosphere in a plasma chamber is disclosed (for example, refer to Patent Reference 2).

[Patent Reference 1] Japanese Unexamined Patent Publication No. 2005-210038 (paragraph [0071]-[0086])

[Patent Reference 2] Japanese Unexamined Patent Publication No. 2005-166925 (a paragraph [0036], FIG. 2)

### SUMMARY OF THE INVENTION

The manufacturing process to the back-grinding of the semiconductor wafer, individually separating this semiconductor wafer to respective chips by dicing, and die bonding which mounts the chip individually separated in a substrate advances as the following.

First, grinder equipment is equipped with a semiconductor wafer after sticking an adhesive tape on the circuit formation surface of a semiconductor wafer. By pressing the rotating abrasive and grinding the back surface of a semiconductor wafer, thickness of a semiconductor wafer is made thin to predetermined thickness (back-grinding step). Then, the back surface of a semiconductor wafer is stuck on the dicing tape fixed to the ring shape frame with a wafer mounting device. An adhesive tape is peeled from the circuit formation surface of a semiconductor wafer (wafer mounting step).

Next, a semiconductor wafer is cut by a predetermined scribe-line, and a semiconductor wafer is individually separated to respective chips (dicing step). As for the chip individually separated, the back surface is pushed and pressed by the pushing-up pin via a dicing tape, and, hereby, a chip peels from a dicing tape. The collet is located in the upper part which faces with a pushing-up pin, and the chip peeled is adsorbed by a collet and held (picking-up step). Then, the chip held at the collet is transported to a wiring substrate, and is joined to the position on a wiring substrate (die-bonding step).

By the way, while a miniaturization and thickness reduction of an electronic apparatus progress, the thickness reduction of the chip mounted in it is demanded. The laminated type semiconductor integrated circuit device which laminates a plurality of chips and is mounted in one package in recent years is developed, and the request to the thickness reduction of a chip is increasing more and more. For this reason, at the back-grinding step, grinding which does thickness of a semiconductor wafer, for example in less than 100 μm is performed. The back surface of the ground semiconductor wafer includes an amorphous layer/polycrystal layer/micro crack layer/an atomic level strain layer (stress gradual shift layer)/a pure crystal layer, among these an amorphous layer/polycrystal layer/micro crack layer is crushing layers (or crystal defect layer). This crushing layer thickness is about 1-2 μm, for example.

When the above-mentioned crushing layer is in the back surface of a semiconductor wafer, the problem that the die strength (the same stress value at the time of a chip breaking when simple bending stress is applied to a chip) of the chip which individually separated the semiconductor wafer falls will happen. Lowering of this die strength appears notably in the chip of less than 100 μm in thickness. Then, lowering of the die strength of a chip is prevented by performing stress relief following a back-grinding, removing a crushing layer, and making the back surface of a semiconductor wafer into a specular surface. In stress relief, a dry-polishing method, the CMP (Chemical Mechanical Polishing) method, or a chemical-etching method is used, for example. That is, to stress relief, grinding or polish of a non-fixed abrasive system, that is, the polishing method by the floating abrasive particle and a polishing pad (a floating abrasive particle is not used in a dry-polishing), the wet etching method by a drug solution, etc. are applied to the crushing layer generated unavoidable in grinding by fixed abrasive (in connection with it, an atomic level strain layer occurs in an interface with a single crystal layer).

However, when the crushing layer of the back surface of a semiconductor wafer is removed, the contamination impurities, and for example, heavy metal impurities, such as the copper (Cu), the iron (Fe), nickel (Ni), or chromium (Cr), adhering to the back surface of the semiconductor wafer will invade into a semiconductor wafer easily. Contamination impurities are mixed in all semiconductor manufacturing devices, such as gas piping and heater wires, and process gas can also constitute a pollution source of contamination impurities. The contamination impurities which invaded from the back surface of a semiconductor wafer diffuse the inside of a semiconductor wafer further, and can draw it near to the crystal defect near the circuit formation surface. The contamination impurities diffused even near the circuit formation surface form the trapping level of a carrier, for example into a forbidden band. For example, the contamination impurities dissoved as solid to silicon oxide/silicon interface make an interface state increase. As a result, the characteristic defect of a semiconductor element resulting from contamination impurities occurs, and lowering of the manufacturing yield of semiconductor products is caused. For example, in the flash memory which is a semiconductor nonvolatile memory, the bad sector at the time of Erase/Write resulting from contamination impurities increases, and characteristic defect occurs, with the number of relief sectors being lacking. In DRAM (Dynamic Random Access Memory) and pseudo-SRAM (Static Random Access Memory), a poor leak system, such as degradation of refreshment (Refresh) characteristics and self refreshment (Self Refresh) characteristics resulting from contamination impurities, occurs. Poor data retention (Data Retention) occurs by the memory of a flash system.

That is, the die strength of a chip is securable with the stress relief after a back-grinding. However, since a crushing layer is lost in this stress relief, the gettering effect over invasion of the contamination impurities from the back surface of a semiconductor wafer falls. If diffusion of contamination impurities may go to near a circuit formation surface, the characteristics of a semiconductor element may be changed and cause a malfunction.

Then, in order to improve the gettering effect, the back surface of the semiconductor wafer which stress relief finished is injected and irradiated abrasive particles with gas, for example like the sandblasting method like the Patent Reference 1. When this forms a damage layer (crushing layer), invasion of the contamination impurities which adhered to the back surface of the semiconductor wafer by this damage layer can be stopped. However, the back surface of the semiconductor wafer which stress relief finished is in the state where the damage layer and the atomic level strain layer (or a part of atomic level strain layer) were removed. So, when a pure crystal layer is irradiated abrasive particles directly, an atomic level strain layer will be again formed in the front surface of a pure crystal layer. Therefore, lowering of the die strength of a chip cannot be prevented.

Since a crushing layer will not be formed in the back surface of a semiconductor wafer when it is the method of forming an oxide film in the back surface of the semiconductor wafer which stress relief finished like Patent Reference 2, lowering of the die strength of a chip can be suppressed. However, in order to acquire the gettering effect with an oxide film, thickness more sufficient than the case where a crushing layer is formed is needed. Since an oxide film is formed by doing a chemical reaction under gas atmosphere, process time is required rather than the method of forming a crushing layer for forming sufficient thickness. In connection with the thickness reduction of a semiconductor chip, the thickness (distance) from the back surface of a semiconductor chip to a circuit formation surface is thin. So, in order to acquire the gettering effect, without affecting the characteristics of the semiconductor element formed in the circuit formation surface, it is difficult to deal with only with an oxide film.

A purpose of the present invention is to offer the technology in which the lowering of the manufacturing yield of semiconductor products resulting from the contamination impurities adhering to the back surface of the semiconductor wafer can be suppressed.

The above-described and the other purposes and novel features of the present invention will become apparent from the description herein and accompanying drawings.

Of the inventions disclosed in the present application, typical ones will next be summarized briefly.

In the manufacturing method of the semiconductor integrated circuit device by the present invention, when making thin a semiconductor wafer, it removes the crushing layer formed by grinding the back surface of a semiconductor wafer with the abrasive which has fixed abrasive. This secures the die strength after dividing or mostly dividing a semiconductor wafer and making a chip. Then, a semiconductor wafer is irradiated with laser beam and the crushing layer which has a gettering function of less than 1.0 μm, less than 0.5 μm, or less than 0.1 μm in thickness in the predetermined region of the predetermined depth from the back surface of a semiconductor wafer, for example is formed newly.

In the other manufacturing method of semiconductor integrated circuit devices by the present invention, when making thin a semiconductor wafer, the crushing layer formed by grinding the back surface of a semiconductor wafer with the abrasive which has fixed abrasive is removed. This secures the die strength after dividing or mostly dividing a semiconductor wafer and making a chip. Then, an insulating film is formed in the back surface of a semiconductor wafer, and the crushing layer with a gettering function of for example, less than 0.05 μm, less than 0.03 μm, or less than 0.01 μm is newly formed in the front surface of the insulating film.

Advantages achieved by some of the most typical aspects of the invention disclosed in the present application will be briefly described below.

Securing the die strength after dividing or mostly dividing the semiconductor wafer made thin and making a chip, invasion of the contamination impurities from the back surface of a semiconductor wafer can be prevented, diffusion of the contamination impurities to the circuit formation surface of a semiconductor wafer can be prevented further, and the generation of the characteristic defect of a semiconductor element can be suppressed.

### BRIEF DESCRIPTION OF THE DRAWINGS

FIG. 1 is a process chart of the manufacturing method of the semiconductor integrated circuit device by Embodiment 1 of the present invention;

FIG. 2 is a principal part side view of the semiconductor integrated circuit device in the manufacturing process by Embodiment 1 of the present invention;

FIG. 3A is a principal part enlarged sectional view of the back surface side portion of the semiconductor wafer after the rough grinding by Embodiment 1 of the present invention, and FIG. 3B is a principal part enlarged sectional view of the back surface side portion of the semiconductor wafer after finish grinding;

FIG. 4A is an explanatory diagram of the equipment to explain the stress relief by the dry-polishing method by Embodiment 1 of the present invention, FIG. 4B is an explanatory diagram of the equipment explaining the stress relief by the CMP method, and FIG. 4C is an explanatory diagram of the equipment explaining the stress relief by a spin-etching method;

FIG. 5A is a principal part enlarged sectional view of the back surface side portion of the semiconductor wafer after the finish grinding by Embodiment 1 of the present invention, FIG. 5B is a principal part enlarged sectional view of the back surface side portion of the semiconductor wafer after stress relief, and FIG. 5C is a principal part enlarged sectional view of the back surface side portion of the semiconductor wafer after micro crack layer formation;

FIG. 6 is an explanatory diagram of the micro crack layer formation by Embodiment 1 of the present invention;

FIG. 7A and FIG. 7B are a principal part side view and a principal part top view of a semiconductor wafer in the manufacturing process which follows FIG. 2, respectively;

FIG. 8 is a principal part side view of the semiconductor integrated circuit device in the manufacturing process following FIG. 7;

FIG. 9 is a principal part side view of the semiconductor integrated circuit device in the manufacturing process following FIG. 8;

FIG. 10 is a principal part side view of the semiconductor integrated circuit device in the manufacturing process following FIG. 9;

FIG. 11 is a principal part side view of the semiconductor integrated circuit device in the manufacturing process following FIG. 10;

FIG. 12 is a principal part side view of the semiconductor integrated circuit device in the manufacturing process following FIG. 11;

FIG. 13 is a principal part cross-sectional view of the semiconductor integrated circuit device in the manufacturing process following FIG. 12;

FIG. 14 is a principal part cross-sectional view of the semiconductor integrated circuit device in the manufacturing process following FIG. 13;

FIG. 15 is a principal part cross-sectional view of the semiconductor integrated circuit device in the manufacturing process following FIG. 14;

FIG. 16 is a principal part cross-sectional view of the semiconductor integrated circuit device in the manufacturing process following FIG. 15;

FIG. 17 is a principal part side view of the semiconductor integrated circuit device in the manufacturing process following FIG. 16;

FIG. 18 is a process chart of the manufacturing method of the semiconductor integrated circuit device by Embodiment 2 of the present invention;

FIG. 19 is a principal part side view of the semiconductor integrated circuit device in the manufacturing process by Embodiment 2 of the present invention;

FIG. 20 is a principal part side view of the semiconductor integrated circuit device in the manufacturing process following FIG. 19;

FIG. 21 is a process chart of the manufacturing method of the semiconductor integrated circuit device by Embodiment 3 of the present invention;

FIG. 22 is a principal part side view of the semiconductor integrated circuit device in the manufacturing process by Embodiment 3 of the present invention; and

FIG. 23 is a principal part side view of the semiconductor integrated circuit device in the manufacturing process following FIG. 22.

### DETAILED DESCRIPTION OF THE PREFERRED EMBODIMENTS

Hereafter, embodiments of the invention are explained in detail based on drawings. In the below-described embodiments, a description will be made after divided into plural sections or in plural embodiments if necessary for convenience sake. These plural sections or embodiments are not independent each other, but in relation such that one is a modification example, details or complementary description of a part or whole of the other one unless otherwise specifically indicated. In the below-described embodiments, when a reference is made to the number of elements (including the number, value, amount and range), the number is not limited to a specific number but may be equal to or greater than or less than the specific number, unless otherwise specifically indicated or principally apparent that the number is limited to the specific number. In the below-described embodiments, it is needless to say that the constituting elements (including element steps) are not always essential unless otherwise specifically indicated or principally apparent that they are essential. In the below-described embodiments, when a reference is made to the shape or positional relationship of the constituting elements, that substantially analogous or similar to it is also embraced unless otherwise specifically indicated or principally apparent that it is not. This also applies to the above-described value and range. In all the drawings for describing the embodiments, members of a like function will be identified by like reference numerals and overlapping descriptions will be omitted. In the drawings used in the below-described embodiments, even a plan view is sometimes partially hatched for facilitating understanding of it.

In the following embodiments, when calling it a semiconductor wafer, it is mainly concerned with Si (silicon) single-crystal wafer. Not only it but an SOI (Silicon on Insulator) wafer, the insulating film substrate for forming an integrated circuit on it, etc. shall be pointed out. The type shall also include not only a circle or almost circular, but a square, a rectangle, etc. When mentioning the member of gas, a solid, or a liquid, it is set as one component of main components specified there. However, except for the case of being theoretically clear or writing clearly such especially, other components are not excepted.

The representative example of an abrasive which has fixed abrasive is the so-called grinding wheel, and has a plurality of fine abrasive particles which are abrasives (for example, diamond etc.), and the binders which combine the abrasive particles of a plurality of (for example, mixtures, such as feldspar and fusibility clay, a good synthetic resin (things other than a synthetic rubber or crude rubber), etc.). The abrasive particle is being fixed in the grinding operation using the abrasive which has fixed abrasive. Since mechanical force is applied to the surface (surface to be ground) where a semiconductor wafer is ground, a crushing layer is formed in the surface of a semiconductor wafer to be ground. There is a floating abrasive particle to fixed abrasive. A floating abrasive particle is abrasive powder included in slurry etc. When this floating abrasive particle is used, since the abrasive particle is not being fixed, usually a crushing layer is not formed in the polish of a semiconductor wafer. Including the case where it polishes only with polishing cloth (dry-polishing), the so-called polishing is classified into the polish using this floating abrasive particle for convenience in a point which does not form a crushing layer.

### Embodiment 1

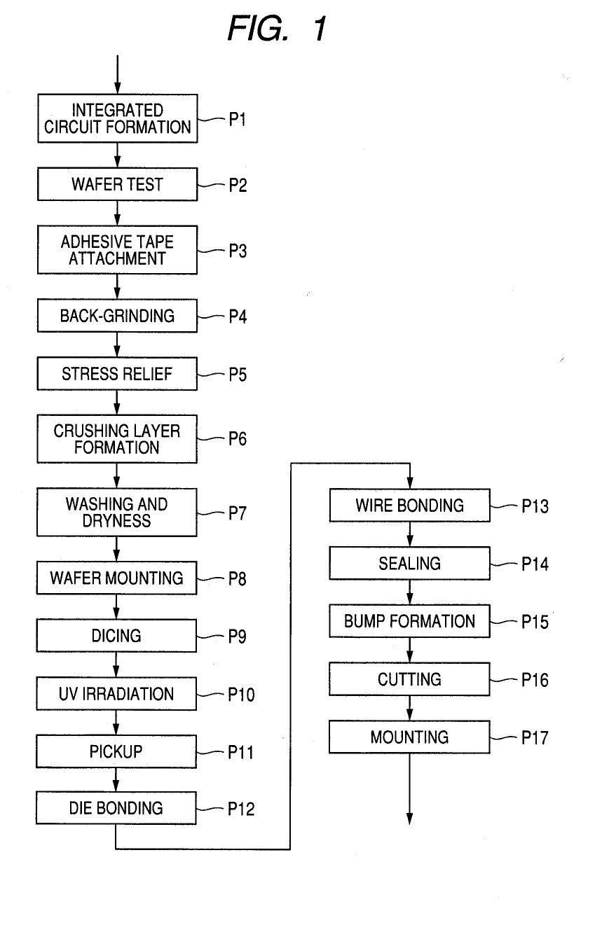

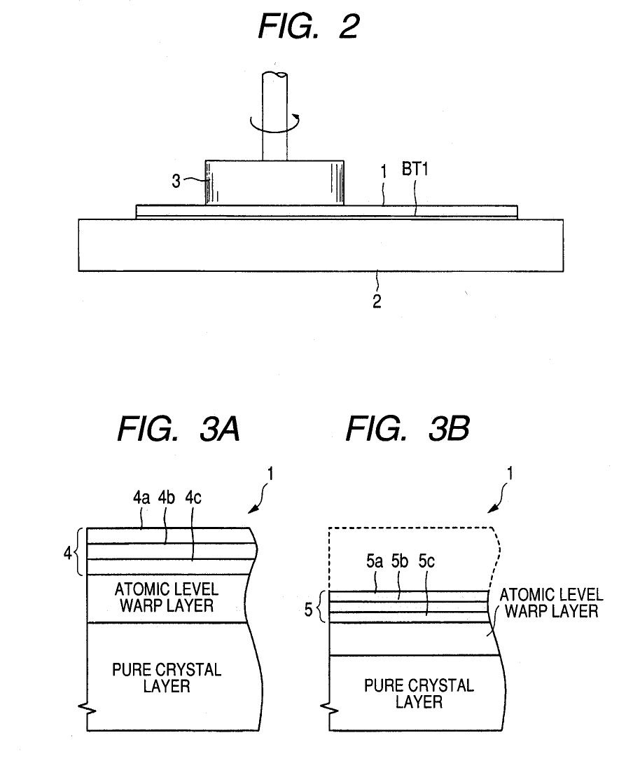

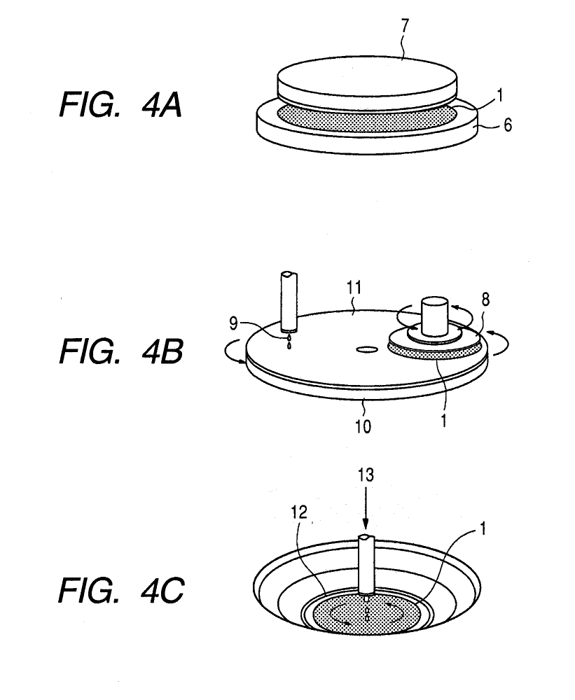

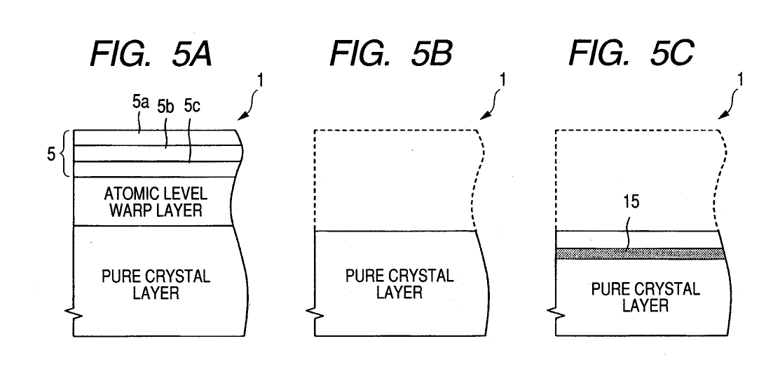

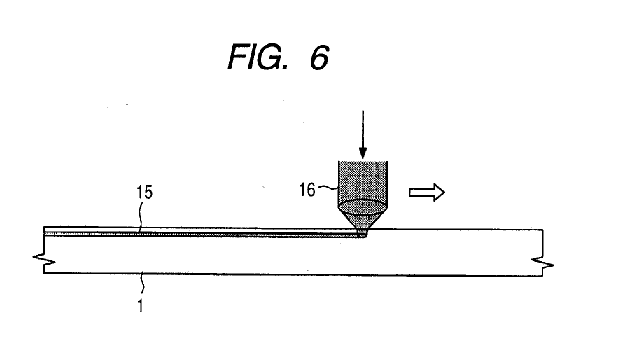

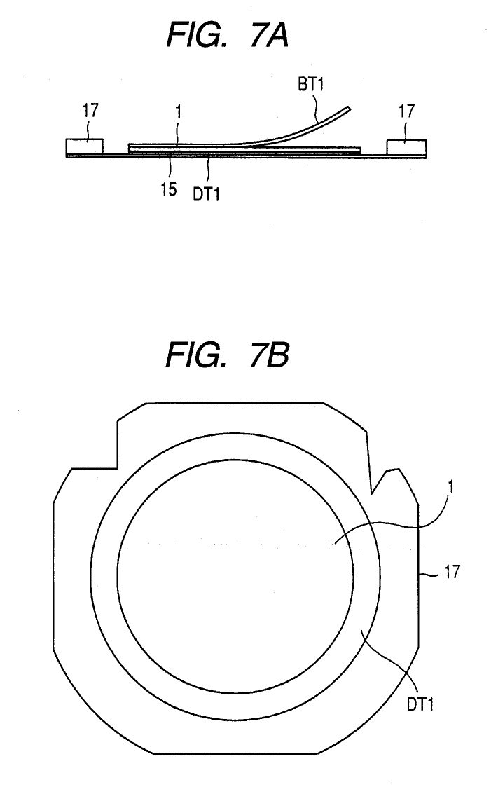

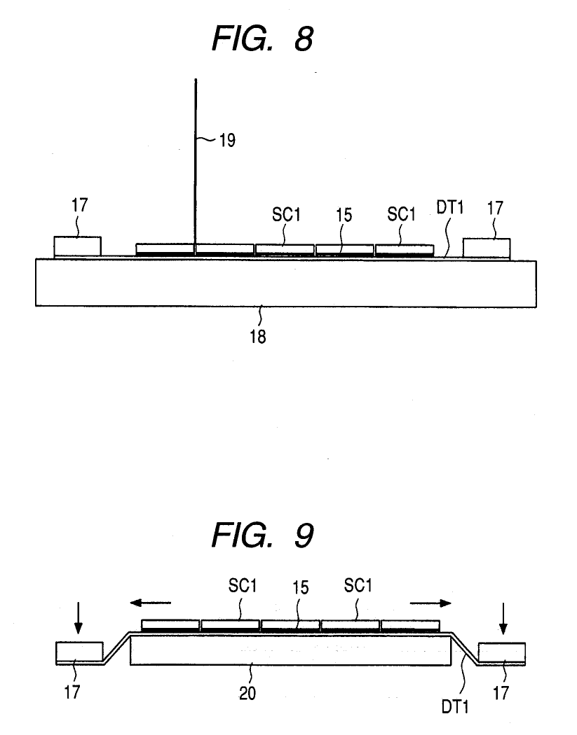

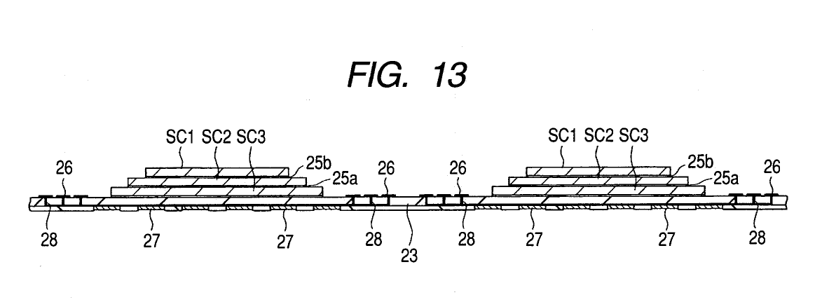

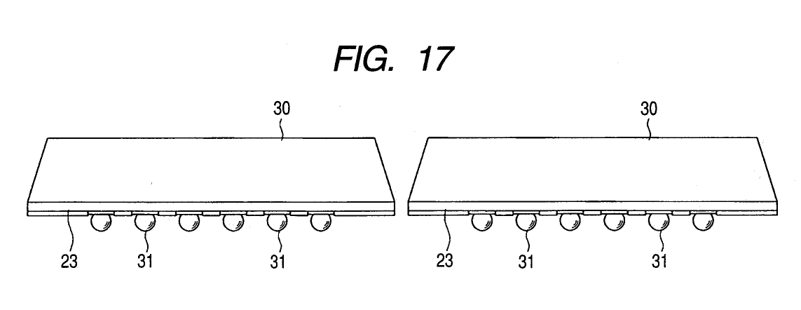

The manufacturing method of the semiconductor integrated circuit device by Embodiment 1 is explained to process order using FIG. 17 from FIG. 1. FIG. 1 is a process chart of the manufacturing method of a semiconductor integrated circuit device, FIG. 2 is a principal part side view of the semiconductor integrated circuit device in a manufacturing process, FIGS. 3A and 3B are principal part enlarged sectional views of the back surface side portion of a semiconductor wafer, FIGS. 4A to 4C are explanatory diagrams of a stress relief system, FIGS. 5A to 5C are principal part enlarged sectional views of the back surface side portion of a semiconductor wafer, FIG. 6 is an explanatory diagram of the micro crack layer formation by laser irradiation, FIGS. 7A and 7B are the principal part side view and a principal part top view of a semiconductor wafer in a manufacturing process, respectively, FIG. 8 to FIG. 12 are principal part side views of the semiconductor integrated circuit device in a manufacturing process, FIG. 13 to FIG. 16 are principal part cross-sectional views of the semiconductor integrated circuit device in a manufacturing process, and FIG. 17 is a principal part side view of the semiconductor integrated circuit device in a manufacturing process. By the following explanation, each step is explained from the back-grinding after forming a circuit pattern on a semiconductor wafer, die bonding which joins the chip individually separated on a wiring substrate, furthermore, such as sealing which protects a plurality of laminated chips by resin etc.

First, an integrated circuit is formed in the circuit formation surface (the first main surface) of a semiconductor wafer (integrated circuit forming step P1 of FIG. 1). A semiconductor wafer includes a silicon single crystal, the diameter is 300 mm, for example, and thickness (first thickness) is more than 700 μm (value at the time of input to a wafer step), for example.

Next, the good and the defect of the respective chips made on the semiconductor wafer are judged (wafer test process P2 of FIG. 1). First, a signal wave form is outputted from an output terminal as laying a semiconductor wafer in the stage for measurement, contacting a probe (probe) to the electrode pad of an integrated circuit, and inputting a signal wave form into it from an input terminal. When a tester reads this, the good and the defect of a chip are judged. Here, the probe card which has arranged the probe according to all the electrode pads of an integrated circuit is used, and from the probe card, the signal line corresponding to each probe has come out, and it connects with the tester. Defective marking is struck by the chip judged to be defective.

Next, an adhesive tape (Pressure-Sensitive adhesive tape) is stuck on the circuit formation surface of a semiconductor wafer (adhesive tape sticking step P3 of FIG. 1). An adhesive tape is a self-peeling type tape here, that is, an ultraviolet-rays (UV) hardening type (UV cure type), a heat-curing type, or an energy beam (EB) hardening type may be used, or non-UV hardening type pressure-sensitive adhesive tape, that is, the common adhesive tape (non-self peeling type tape) which is not UV hardening type, a heat-curing type, or EB hardening type may be used. In the case of a non-self peeling type tape, self-detachability cannot be used. However, it has a good point to be able to avoid change of the write-in information on memory system circuits, such as a nonvolatile memory, generated when irradiating ultraviolet rays, an energy ray, or heat rays to the circuit formation surface of a wafer, characteristics shift, and change with undesirable surface characteristics, such as surface-protection members, such as a polyimide layer, or a wiring insulating member.

Below, the example of a non-self peeling type tape is explained. The adhesive is applied to the adhesive tape and this sticks an adhesive tape with the circuit formation surface of a semiconductor wafer. An adhesive tape uses polyolefine as a base material, for example, the adhesive of an acrylic system is applied, and the release material which includes polyester on it further is stuck. A release material is a mold-releasing paper, for example, a release material is removed and an adhesive tape is stuck on a semiconductor wafer. The thickness of an adhesive tape is 130-150 μm, and adhesive power is 20-30 g/20 mm (it expresses as the strength at the time of the tape of 20 mm width peeling), for example. The adhesive tape which did mold-releasing-processing the back surface of the base material may be used without release material.

Next, the back surface (the opposite side of the surface of a circuit formation surface, the second main surface) of a semiconductor wafer is ground. Thickness of a semiconductor wafer is made predetermined thickness, for example, less than 100 μm, less than 80 μm, or less than 60 μm (back-grinding step P4 of FIG. 1). In this back-grinding, the rough grinding and finish grinding which are explained below are performed one by one.

First, as shown in FIG. 2, the back surface of semiconductor wafer 1 is performed rough grinding. Semiconductor wafer 1 is transported to grinder equipment, and by pressing rotating first abrasive 3 (for example from fineness number #320 to #360 of polish powder: Fineness number # showing the diameter of a polish or grinding abrasive particle corresponds to the size of the opening of sieve at the time of sifting the diamond wheel at the time of manufacturing a grinding wheel etc. In other words, it corresponds to the diameter of main abrasive particles. When an example is shown, the particle diameter of #280 is about 100 μm, the particle diameter of #360 is about 40 to 60 μm, the particle diameter of # 2000 is about 4 to 6 μm, the particle diameter of #4000 is about 2 to 4 μm and the particle diameter of #8000 is about 0.2 μm. The present application describes the diameter of an abrasive particle based on this. There is Japanese Industrial Standards regarding less than #320.) and performing rough grinding at the back surface of semiconductor wafer 1 after doing vacuum adsorption of the circuit formation surface of semiconductor wafer 1 to chuck table 2, the thickness of semiconductor wafer 1 is made to decrease to a predetermined thickness (second thickness). First abrasive 3 is an abrasive which has fixed abrasive, and for example from about 600 to 700 μm grinding of the semiconductor wafer 1 is done by this rough grinding. Less than 140 μm of the second thickness of semiconductor wafer 1 which remains by this rough grinding is a suitable range, for example (naturally depending on other conditions, not limited to this range). Although less than 120 μm can be considered as a range suitable for mass production, it is thought that the range of less than 100 μm is still more preferred. Since adhesive tape BT1 is stuck on the circuit formation surface of semiconductor wafer 1, an integrated circuit is not destroyed. In a general process, it is thought that more than #100 less than #700 is suitable for the size range of the above-mentioned first abrasive 3.

Then, the back surface of semiconductor wafer 1 is performed finish grinding. By pressing rotating second abrasive (from fineness number #1500 to #2000, for example, of polish powder) and performing finish grinding at the back surface of semiconductor wafer 1, after doing vacuum adsorption of the circuit formation surface of semiconductor wafer 1 to a chuck table here using the same grinder equipment as the FIG. 2, warp of the back surface of semiconductor wafer 1 generated at the time of the above-mentioned rough grinding is removed, and simultaneously, the thickness of semiconductor wafer 1 is made to decrease to predetermined thickness (third thickness). A second abrasive is an abrasive which has fixed abrasive, and for example about from 25 to 40 μm grinding of the semiconductor wafer 1 is done by this finish grinding. As for the third thickness of semiconductor wafer 1 which remains by this finish grinding, less than 100 μm is considered to be a suitable range, for example (naturally depending on other conditions, not limited to this range). Although less than 80 μm can be considered as a range suitable for mass production, it is thought that the range of less than 60 μm is still more preferred.

FIG. 3A shows the principal part enlarged sectional view of the back surface side portion of semiconductor wafer 1 performed rough grinding using the above-mentioned first abrasive, and FIG. 3B shows the principal part enlarged sectional view of the back surface side portion of semiconductor wafer 1 performed finish grinding using the above-mentioned second abrasive. In rough grinding, an atomic level warp layer and crushing layer 4 (amorphous layer 4a/polycrystal layer 4b/micro crack layer 4c) are formed on the pure crystal layer of the back surface of semiconductor wafer 1. Also in finish grinding, an atomic level warp layer and first crushing layer 5 (amorphous layer 5a/polycrystal layer 5b/micro crack layer 5c) are formed on the pure crystal layer of the back surface of semiconductor wafer 1. However, the thickness of a pure crystal layer and atomic level warp layer and first crushing layer 5 becomes thinner than the thickness of the pure crystal layer and atomic level warp layer and crushing layer 4 after rough grinding, respectively. As for the thickness of this first crushing layer 5, less than 2 μm is considered to be a suitable range, for example (naturally depending on other conditions, not limited to this range). Although less than 1 μm can be considered as a range suitable for mass production, it is thought that the range of less than 0.5 μm is still more preferred.

Next, stress relief removes first crushing layer 5 and an atomic level warp layer (stress relief step P5 of FIG. 1). The die strength of a chip can be raised by removing this first crushing layer 5 and an atomic level warp layer. When removing first crushing layer 5 and an atomic level warp layer, it may leave a part of atomic level warp layer.

First, vacuum adsorption of the back surface of semiconductor wafer 1 by which vacuum adsorption was done to the chuck table of the grinder equipment which performed finish grinding in the circuit formation surface is done by a wafer transport jig. By cutting the vacuum of a chuck table, semiconductor wafer 1 is held by a wafer transport jig, and semiconductor wafer 1 is transported to stress relief equipment as it is. Furthermore, after vacuum adsorption of the semiconductor wafer 1 is done to the rotating table or pressurizing head of stress relief equipment in the circuit formation surface, stress relief is given.

In this stress relief, as shown, for example in FIGS. 4A to 4C, a dry-polishing method (FIG. 4A), the CMP method (FIG. 4B), or a chemical-etching method (FIG. 4C) is used. A dry-polishing method is a method of polishing the back surface of semiconductor wafer 1 mounted on rotating table 6 with polishing cloth 7 (Cloth which silica was made to adhere with a binder on the surface of a fiber, for example, was hardened with φ about 400 mm and a thickness of about 26 mm in the shape of a pad: Dry Polish Wheel) to which the abrasive particle adhered. This dry-polishing method can make cost cheaper than other methods. The CMP method is the method of making stick the back surface of semiconductor wafer 1 to polishing pad 11 stuck on the front surface of platen (surface table) 10 by pressure, and polishing, holding semiconductor wafer 1 by pressurizing head 8, and passing slurry (polish abrasive liquid) 9. A uniform processed surface can be obtained by this CMP method. A chemical-etching method is the method of mounting semiconductor wafer 1 on rotating table 12, and etching using mixed-solution of fluoric acid and nitric acid (HF+HNO₃) 13. There is an advantage that there are many amounts of removal in this chemical-etching method.

Next, as shown in FIG. 5, second crushing layer (micro crack layer) 15 is formed in the predetermined region (for example, almost whole surface except the peripheral part of the chip) of the predetermined depth from the back surface of semiconductor wafer 1 (crush-layer-forming step P6 of FIG. 1). The depth from the back surface of semiconductor wafer 1 in which second crushing layer 15 is located will not be limited in particular, when it is the depth which does not affect the characteristics of the semiconductor element formed in the circuit formation surface of semiconductor wafer 1. For example, second crushing layer 15 is formed in from the back surface of semiconductor wafer 1 before the half of the thickness of semiconductor wafer 1. FIG. 5 is a principal part cross-sectional view of the back surface side portion of semiconductor wafer 1. FIGS. 5A, 5B and 5C show semiconductor wafer 1 performed finish grinding using the second abrasive, semiconductor wafer 1 which gave stress relief, and semiconductor wafer 1 in which second crushing layer 15 was formed, respectively.

After stress relief finished, when first crushing layer 5 (amorphous layer 5a/polycrystal layer 5b/micro crack layer 5c) formed in the back surface of semiconductor wafer 1 by finish grinding was removed and a pure silicon crystal structure part is exposed, and contamination impurities, for example, heavy metal impurities etc., adhere to the back surface of semiconductor wafer 1, it will invade into semiconductor wafer 1 easily. The contamination impurities which invaded into semiconductor wafer 1 diffuse the inside of semiconductor wafer 1, and reach to the circuit formation surface of semiconductor wafer 1, and there is a problem of causing the characteristic defect of the semiconductor element formed in the circuit formation surface. Also in a heavy metal, the diffusion coefficient of Cu is 6.8×10⁻²/sec(at 150° C.) and high as compared with the diffusion coefficient (the diffusion coefficient of Fe is 2.8×10⁻¹³/sec(at 150° C.)) of other heavy metals. Since it is easy to reach to the circuit formation surface of semiconductor wafer 1, it is thought that it is one of the main contamination impurities which cause the characteristic defect of a semiconductor element. The binder layer of a dicing tape and the binder layer for die bonding can be mentioned to this source of invasion of Cu, for example. Into these binder layer, a little Cu(s) may be mixing with various impurities and foreign substances (filler). And since these binder layer touches the back surface of semiconductor wafer 1 or a chip directly, invasion of Cu is easy.

So, in Embodiment 1, as shown in FIG. 5C, it dares form in the predetermined region of the predetermined depth second crushing layer 15 which has gettering capability (Generally the capability to capture, to be fixed and to detoxicate it is said so to pollution goods, such as a metal harmful when making a semiconductor element) from the back surface of semiconductor wafer 1. Invasion and diffusion of the contamination impurities to semiconductor wafer 1 are suppressed by this second crushing layer 15.

This second crushing layer 15 is a micro crystal defect layer, for example. As for the thickness, less than 1.0 μm (that is, it is more advantageous to be comparatively thicker in order to secure the die strength of a chip) is considered to be a suitable range, for example (naturally depending on other conditions, not limited to this range). Although less than 0.5 μm can be considered as a range suitable for mass production, it is thought that the range (it is because it is satisfactory when it is more than the lower limit which can prevent invasion and diffusion of contamination impurities) of less than 0.1 μm is still more preferred.

Formation of second crushing layer 15 is performed by irradiation of the laser beam to semiconductor wafer 1 described below. First, vacuum adsorption of the semiconductor wafer 1 by which vacuum adsorption was done to the rotating table or pressurizing head of stress relief equipment is done by a wafer transport jig. By cutting the vacuum of a rotating table or a pressurizing head, semiconductor wafer 1 is held by a wafer transport jig, and semiconductor wafer 1 is transported to laser beam irradiation equipment as it is. For example, vacuum adsorption of the semiconductor wafer 1 transported by laser beam irradiation equipment is done to the chuck table of laser beam irradiation equipment etc. in the circuit formation surface.

Next, as shown in FIG. 6, laser beam 16 is condensed at minute spot, and second crushing layer 15 is formed in the predetermined region of the predetermined depth from the back surface of semiconductor wafer 1 by scanning this by arbitrary loci from the back surface side of semiconductor wafer 1. On this occasion, for example, by dropping the strength of laser beam 16 suitably, or expanding irradiation area by a magnifying optical system (lens system) etc., laser beam 16 of the optimal energy is irradiated and scanned. Hereby, necessary minimum second crushing layer 15 can be formed in the predetermined region of the predetermined depth from the back surface of semiconductor wafer 1. The near infrared rays (a wavelength is 800-3000 nm) belonging to infrared rays are used for a laser beam. As conditions for a laser beam, the wavelength of 1064 nm, the scanning speed of 600mm/second, and spot diameter 2˜3 μm can be exemplified. Since the die strength of a chip may fall when second crushing layer 15 is formed all over semiconductor wafer 1 (all the plane regions in the layer which irradiates a laser beam), it is desirable to leave predetermined width from the periphery of a chip and to irradiate a laser beam. As for the above-mentioned predetermined width, less than 5.0 μm is considered to be a suitable range, for example (naturally depending on other conditions, not limited to this range). Although less than 3.0 μm can be considered as a range suitable for mass production, it is thought that less than 1.0 μm is still more preferred.

As a semiconductor wafer which has gettering capability, there is an epitaxial wafer in which for example, the epitaxial layer (for example, the p type epitaxial layer which has impurity concentration lower than the above-mentioned p+ type substrate) of the thickness of 50 to 100 μm was formed to the substrate (for example, p+ type substrate) which includes a silicon single crystal with which the high-concentration impurity was introduced with an epitaxial grown method. Although an epitaxial layer is a defect-free layer, gettering capability is given by introducing a high-concentration impurity into a substrate. However, when grinding an epitaxial wafer from a back surface and making the thickness, for example less than 100 μm, the portion of the substrate which has gettering capability will disappear from the request to the thickness reduction of a chip. Therefore, even if it uses an epitaxial wafer, it is necessary to form a micro crystal defect layer in the predetermined region of the predetermined depth from the back surface of a semiconductor wafer.

Thus, according to Embodiment 1, first crushing layer 5 (for example, the thickness is less than 2 μm, less than 1 μm, or less than 0.5 μm) of the back surface of semiconductor wafer 1 formed of the back-grinding was removed by stress relief in order to raise the die strength of a chip, and the pure crystal layer has exposed it. However, invasion of the contamination impurities from the back surface of semiconductor wafer 1 can be prevented simultaneously, without reducing the die strength of a chip by forming second crushing layer 15 (for example, the thickness is less than 1.0 μm, less than 0.5 μm, or less than 0.1 μm) in the predetermined region of the predetermined depth from the back surface of the semiconductor wafer 1. As another reason that chip die strength does not fall, a part of pure crystal layer melts by irradiating a laser beam, and after that, the layer of hardness strong against mechanical stress has been formed in second crushing layer 15 because the region by which melting was done solidifies again. Furthermore, second crushing layer 15 can prevent diffusion of the contamination impurities to the circuit formation surface of semiconductor wafer 1, and can prevent the characteristic defect of the semiconductor element resulting from contamination impurities. Hereby, lowering of the manufacturing yield of semiconductor products can be suppressed.

Next, after washing and drying semiconductor wafer 1 (washing and drying step P7 of FIG. 1), as shown in FIGS. 7A and 7B, semiconductor wafer 1 is stuck on dicing tape DT1 again (wafer mounting step P8 of FIG. 1). First, vacuum adsorption of the semiconductor wafer 1 is done by a wafer transport jig, and it transports to a wafer mounting device as it is. Semiconductor wafer 1 transported by the wafer mounting device is sent to an alignment part, and alignment of a notch or an orientation flat is performed. Then, semiconductor wafer 1 is sent to a wafer mount part, and wafer mounting is performed. In wafer mounting, annular frame 17 which stuck dicing tape DT1 beforehand is prepared. To this dicing tape DT1, the circuit formation surface is used as the upper surface, and semiconductor wafer 1 is stuck. Dicing tape DT1 uses polyolefine as a base material, for example, an acrylic system UV hardening type adhesive is applied, and the release material which includes polyester is further stuck on it. A release material is a mold-releasing paper, for example, a release material is removed and dicing tape DT1 is stuck on semiconductor wafer 1. The thickness of dicing tape DT1 is 90 μm, and adhesive power is 200 g/25 mm before UV irradiation, and 10˜20 g/25 mm after UV irradiation, for example. The dicing tape which did mold-releasing-processing the back surface of the base material may be used without release material.

Subsequently, frame 17 equipped with semiconductor wafer 1 is sent to an adhesive tape stripping part. Here, adhesive tape BT1 peels from semiconductor wafer 1. Thus, resticking semiconductor wafer 1 on frame 17 is because dicing is performed at a later dicing step on the basis of the alignment mark currently formed in the circuit formation surface of semiconductor wafer 1, so it is necessary to use as the upper surface the circuit formation surface in which the alignment mark is formed. Since semiconductor wafer 1 is fixed via dicing tape DT1 stuck on frame 17 even if adhesive tape BT1 peels, a warp of semiconductor wafer 1 does not surface.

Next, as shown in FIG. 8, dicing of the semiconductor wafer 1 is done (dicing step P9 of FIG. 1). Although semiconductor wafer 1 is individually separated by chip SC1, since respective-chips SC1 is being fixed to frame 17 via dicing tape DT1 even after individually separating, the state where it aligned is maintained. First, vacuum adsorption of the circuit formation surface of semiconductor wafer 1 is done by a wafer transport jig, semiconductor wafer 1 is transported to a dicing apparatus as it is, and it lays on dicing table 18. Then, semiconductor wafer 1 is cut vertically and horizontally using ultra thin circular blade 19 which is called a diamond saw and which stuck the diamond particle along a scribe-line (line with which the chip boundary was underlined in order to carve into each chip from semiconductor wafer 1).

Next, as shown in FIG. 9, semiconductor wafer 1 is again mounted on up to other tables 20 from dicing table 18 of a dicing apparatus. Then, frame 17 is depressed and chip SC1 is separately divided by extending dicing tape DT1. Although this method is called the so-called expand system, it is not limited to this as a method of dividing chip SC1 separately. For example, the so-called cracking system that divides chip SC1 separately by applying the force to chip SC1 of each row is also employable.

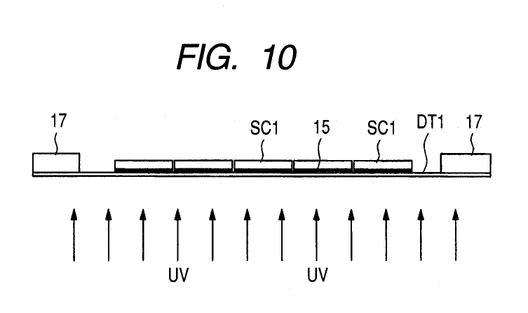

Next, as shown in FIG. 10, semiconductor wafer 1 is irradiated ultraviolet rays (UV) (UV irradiation step P10 of FIG. 1). UV is irradiated from the back surface side of dicing tape DT1, and the adhesive power of the surface which touches respective-chips SC1 of dicing tape DT1 is reduced, for example to about 10˜20 g/25 mm. Hereby, respective-chips SC1 separates easily from dicing tape DT1.

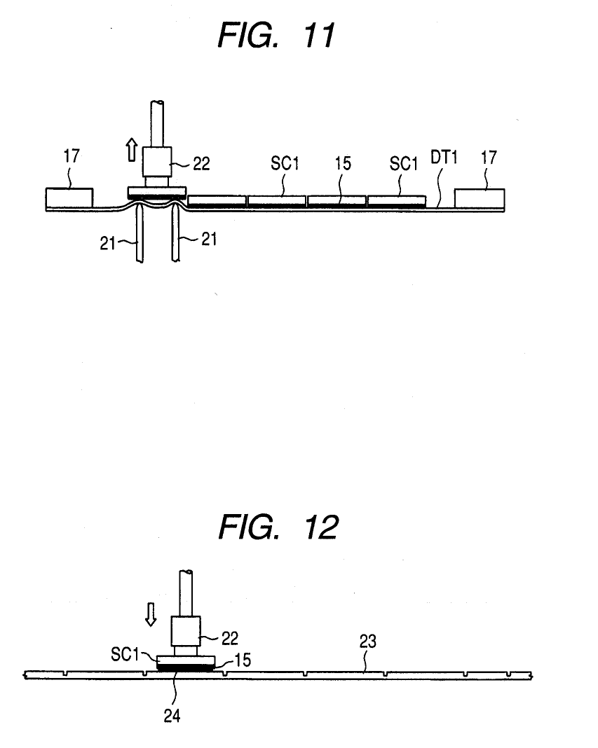

Next, as shown in FIG. 11, chip SC1 judged to be good in wafer test process P2 of FIG. 1 is picked up (picking-up step P11 of FIG. 1). First, the back surface of chip SC1 is pushed and pressed via dicing tape DT1 by pushing-up pin 21, and this peels chip SC1 from dicing tape DT1. Then, collet 22 moves and is located in the upper part which faces with pushing-up pin 21, and vacuum adsorption of the circuit formation surface of chip SC1 which peeled is done by collet 22. Hereby, it tears off and picks up one chip SC1 at a time from dicing tape DT1. Since the adhesive strength of dicing tape DT1 and chip SC1 can be weakening by UV irradiation, even if it is chip SC1 to which strength is falling thinly, it can pick up surely. Collet 22 has a contour of an abbreviation cylinder type, for example, and the adsorption part located in the bottom comprises an elastic synthetic rubber etc., for example.

Next, as shown in FIG. 12, chip SC1 used as the first stage is mounted in wiring substrate 23 (die-bonding step P12 of FIG. 1).

First, collet 22 is adsorbed, and chip SC1 picked up is held at it, and it is transported in the specified position on wiring substrate 23. Then, paste material 24 is mounted on the island (chip mounting region) of wiring substrate 23, chip SC1 is pushed and attached here lightly, and the temperature about 100˜200° C. performs curing treatment. This sticks chip SC1 on wiring substrate 23. As paste material 24, epoxy system resin, polyimide system resin, acrylic system resin, or silicone system resin can be exemplified. Except for the attachment by paste material 24, the back surface of chip SC1 may be rubbed against an island lightly, or by inserting the bit of a gold tape between the island and chip SC1 which were plated, the eutectic of gold and silicon may be made and it may adhere. When chip SC1 is mounted on the plated island, it is possible to improve the heat radiation property of chip SC1.

After die bonding of a non defective unit chip and the removal of a defective unit chip which were stuck by dicing tape DT1 are completed, dicing tape DT1 is removed from frame 17, and frame 17 is recycled.

Next, as shown in FIG. 13, chip SC2 is prepared like the chip SC1, and chip SC2 which becomes the second stage is joined on chip SC1 of the first stage using insulating paste 25a, for example. Next, chip SC3 is prepared like the chip SC1, and chip SC3 which becomes the third stage is joined on chip SC2 of the second stage using insulating paste 25b, for example. In this way, chip SC1, SC2, and SC3 are stacked. Chip SC1 of the first stage is a microcomputer, for example, chip SC2 of the second stage is electrically batch erasing type EEPROM (Electric Erasable Programmable Read Only Memory) for example, and chip SC3 of the third stage can exemplify SRAM, for example. A plurality of electrode pads 26 are formed in the front surface of this wiring substrate 23, a plurality of connection pads 27 are formed in the back surface, and both are electrically connected by wiring 28 in a substrate.

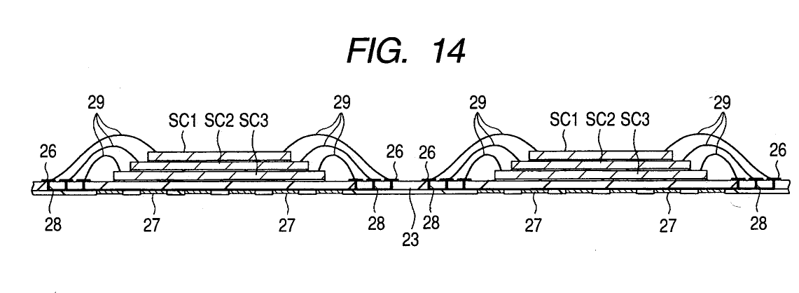

Next, as shown in FIG. 14, the bonding pad arranged on the border of the front surface of each chip SC1, SC2, or SC3 and electrode pad 26 of the front surface of wiring substrate 23 are connected using bonding wire 29 (wire-bonding step P13 of FIG. 1). It automates and the work is done using a bonding device. The arrangement information of the bonding pad of stacked chip SC1, SC2, and SC3 and electrode pad 26 of the front surface of wiring substrate 23 is beforehand inputted into the bonding device. The relative location relation of stacked chip SC1, SC2, and SC3 mounted on wiring substrate 23, the bonding pad of the front surface and electrode pad 26 of the front surface of wiring substrate 23 is incorporated as a picture, data processing is performed, and bonding wire 29 is connected correctly. On this occasion, the loop shape of bonding wire 29 is controlled by the type which rose to be unable to touch the periphery of stacked chip SC1, SC2, and SC3.

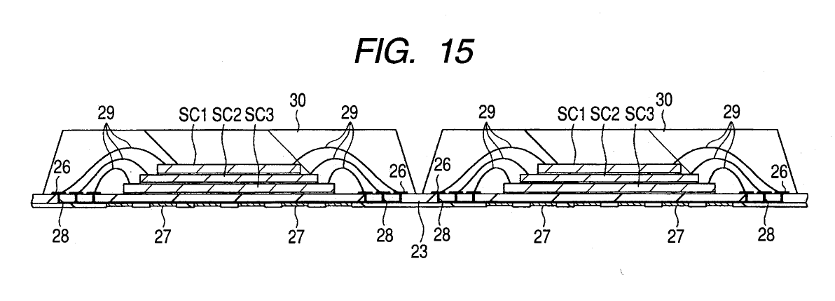

Next, as shown in FIG. 15, wiring substrate 23 to which bonding wire 29 was connected is set to a metallic molding machine, and resin 30 which raised temperature and liquefied is pressurized and sent and poured in. Stacked chip SC1, SC2, and SC3 are enclosed, and mold formation is done (molding step P14 of FIG. 1). Then, excessive resin 30 or a burr is removed.

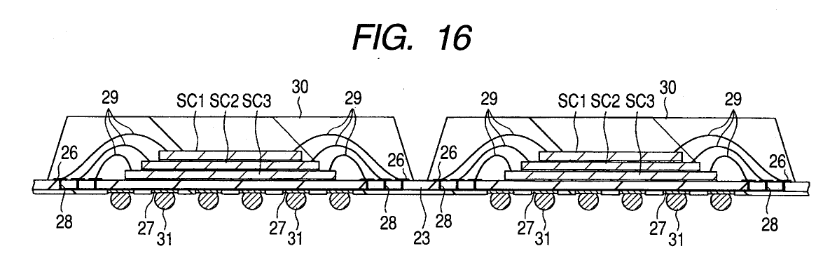

Next, as shown in FIG. 16, bump 31 which includes solder is supplied to connection pad 27 of the back surface of wiring substrate 23. Then, reflow treatment is performed, melting of the bump 31 is done, and bump 31 and connection pad 27 are connected (bump forming step P15 of FIG. 1).

Then, as shown in FIG. 17, on resin 30, a name of article etc. is sealed and each stacked chip SC1, SC2, and SC3 is carved from wiring substrate 23 (cutting step P16 of FIG. 1). Then, the product which includes finished each stacked chip SC1, SC2, and SC3 is sorted out along product quality standards, and a product is completed through a test step (assembling step P17 of FIG. 1).

### Embodiment 2

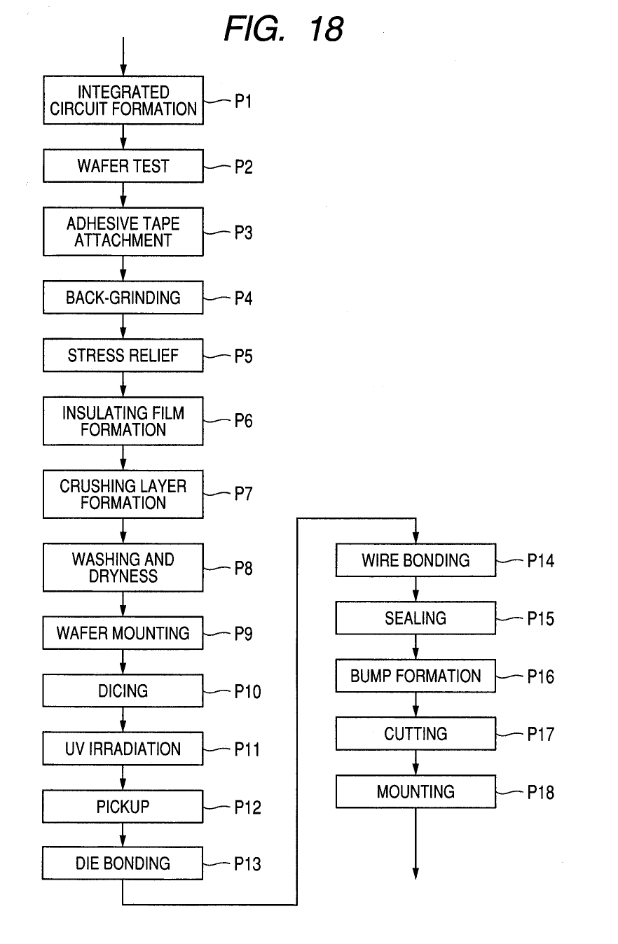

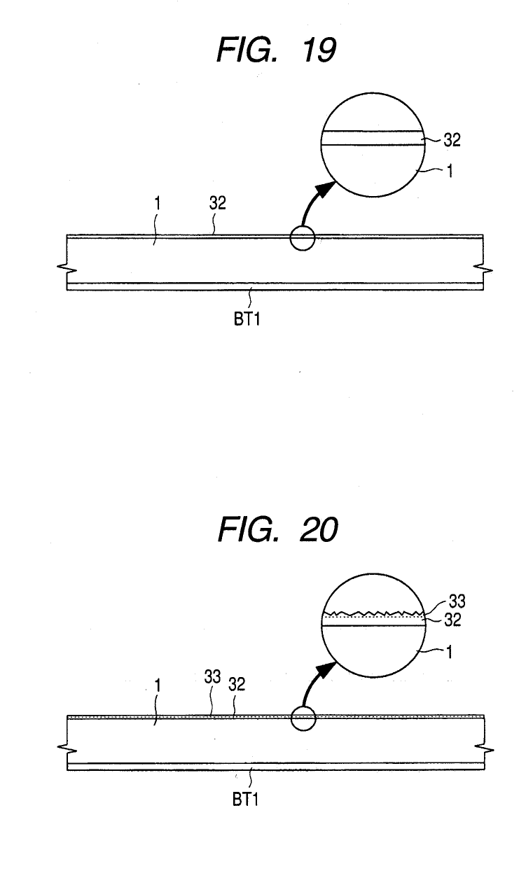

In the Embodiment 1, second crushing layer 15 which has gettering capability was formed in the predetermined region of the predetermined depth from the back surface of semiconductor wafer 1. However, in Embodiment 2, an insulating film is formed in the back surface of semiconductor wafer 1, and the third crushing layer which has gettering capability is formed in the front surface of the insulating film. Therefore, the step which is different from the Embodiment 1 in Embodiment 2 is a crush-layer-forming step. So, the steps from an integrated circuit forming step to the stress relief step and the steps from washing and a drying step to the assembling step which are the same steps as the Embodiment 1 are omitted. The following explanation explains a crush-layer-forming step. The manufacturing method of the semiconductor integrated circuit device by Embodiment 2 is explained to process order using FIG. 20 from FIG. 18. FIG. 18 is a process chart of the manufacturing method of a semiconductor integrated circuit device, and FIG. 19 and FIG. 20 are the principal part side views of the semiconductor integrated circuit device in a manufacturing process.

First, the back surface of semiconductor wafer 1 is ground and the thickness of semiconductor wafer 1 is made predetermined thickness, for example, less than 100 μm, less than 80 μm, or less than 60 μm (back-grinding step P4 of FIG. 18). In this back-grinding, rough grinding and finish grinding are performed one by one like the Embodiment 1. Then, stress relief removes first crushing layer 5 (stress relief step P5 of FIG. 18).

Next, as shown in FIG. 19, insulating film 32 about thickness 0.1 μm is formed in the back surface of semiconductor wafer 1, for example (insulating film forming step P6 of FIG. 18). Insulating film 32 is a silicon oxide film, for example, and is formed by the thermal oxidation method or the CVD (Chemical Vapor Deposition) method.

First, vacuum adsorption of the semiconductor wafer 1 by which vacuum adsorption was done to the rotating table or pressurizing head of stress relief equipment is done by a wafer transport jig. By cutting the vacuum of a rotating table or a pressurizing head, semiconductor wafer 1 is held by a wafer transport jig, and semiconductor wafer 1 is transported to an insulating film forming device as it is. Vacuum adsorption of the semiconductor wafer 1 transported by the insulating film forming device is done, for example to the chuck table of an insulating film forming device etc. in the circuit formation surface, and insulating film 32 is formed in the back surface.

Next, as shown in FIG. 20, third crushing layer (micro crack layer) 33 is formed in the front surface of insulating film 32 (crush-layer-forming step P7 of FIG. 18). The front surface (refer to the FIG. 19) of insulating film 32 immediately after formation is a specular surface, and the gettering effect is weak. When forming the thickness of insulating film 32 thickly, the gettering effect will go up, but as described above, in connection with the thickness reduction of semiconductor wafer 1, it becomes difficult to form insulating film 32 thickly. So, at Embodiment 2, a certain amount of gettering effect is given by forming insulating film 32 about thickness 0.1 μm. In order to compensate the gettering effect furthermore, invasion and diffusion of the contamination impurities to semiconductor wafer 1 are suppressed by forming a third crushing layer in the front surface of insulating film 32.

Third crushing layer 33 is a micro crystal defect layer, for example, and less than 0.05 μm, for example in the thickness (that is, it is more advantageous to be comparatively thinner in order to secure the die strength of a chip) is considered to be a suitable range (naturally depending on other conditions, not limited to this range). Although less than 0.03 μm can be considered as a range suitable for mass production, it is thought that the range (it is because it is satisfactory when it is more than the lower limit which can prevent invasion and diffusion of contamination impurities) of less than 0.01 μm is still more preferred.

Formation of third crushing layer 33 is performed by either of the first or second methods of describing below, for example. First, vacuum adsorption of the semiconductor wafer 1 by which vacuum adsorption was done to the chuck table of the insulating film forming device etc. is done by a wafer transport jig. By cutting the vacuum of a chuck table etc., semiconductor wafer 1 is held by a wafer transport jig, and semiconductor wafer 1 is transported to a crushing layer forming device as it is. Vacuum adsorption of the semiconductor wafer 1 transported by the crushing layer forming device is done, for example to the chuck table of a crushing layer forming device etc. in the circuit formation surface, and third crushing layer 33 is formed in the back surface.

By the first method, third crushing layer 33 is formed in the front surface of insulating film 32 with sandblasting. Then, while injecting an abrasive particle with for example, the gas which pressurized about 2˜3 kgf/cm2 and washing the front surface of insulating film 32, third crushing layer 33 is further formed in the front surface of the washed insulating film 32. Abrasive particles are SiC and alumina, for example, and the particle diameter is about several to several 10 μm, for example. Then, a masking material is removed and semiconductor wafer 1 is washed. Here, in Embodiment 2, insulating film 32 is intentionally formed with the thermal oxidation method or the CVD method. However, even if leaving semiconductor wafer 1 as it is, insulating film 32 is formed in the front surface of semiconductor wafer 1 as a natural-oxidation film. However, in the case of a natural-oxidation film, about 0.01 μm of the thickness of the insulating film formed is a limit. Therefore, when the back surface of semiconductor wafer 1 is irradiated by the sandblasting method in this state, an atomic level warp layer is formed more than the thickness of insulating film 32 currently formed in the back surface of semiconductor wafer 1, and as described above, it becomes lowering of chip die strength. So, in Embodiment 2, even if it applies the sandblasting method, the insulating film about 0.1 μm is formed with the thermal oxidation method or CVD method which can ease the warp layer formed by insulating film 32.

By the second method, the long wavelength ultraviolet-rays (UV laser light) irradiation belonging to ultraviolet rays is used. The wavelength of long wavelength ultraviolet rays (UVA) is 320-400 nm. That is, in Embodiment 2, the upper surface of insulating film 32 is irradiated by UV laser with a wavelength of 355 nm, for example, and third crushing layer 33 is formed in the front surface of insulating film 32 by the energy. Here, the reason for using UV laser light is that when it is near infrared rays, it is possible to irradiate the internal layer of semiconductor wafer 1, but when it is not ultraviolet rays with a low wavelength to irradiate the front surface of semiconductor wafer 1, semiconductor wafer 1 will be penetrated. Although it is dependent also on the condition, the first method of the above using sandblasting may give the damage which drops the die strength of a chip to the back surface of semiconductor wafer 1, when forming third crushing layer 33. However, by this second method of using UV laser photoirradiation for the back surface of semiconductor wafer 1, when forming third crushing layer 33, some damage is given to the back surface of semiconductor wafer 1. However, since the layer of hardness strong against mechanical stress is formed because melting of a part of semiconductor wafers 1 is done and the region by which melting was done solidifies again after that as described above, the die strength of a chip is securable.

Then, by passing washing and drying step P8, wafer mounting step P9, dicing step P10, UV irradiation step P11, picking-up step P12, die-bonding step P13, etc. one by one like the Embodiment 1, the product shown in the FIG. 17, for example is completed.

Thus, according to Embodiment 2, first crushing layer (for example, less than 2 μm, less than 1 μm, or less than 0.5 μm in thickness) 5 of the back surface of semiconductor wafer 1 formed of the back-grinding was removed by stress relief, and the pure crystal layer has exposed it. However, by forming third crushing layer (for example, the thickness is less than 0.05 μm, less than 0.03 μm, or less than 0.01 μm) 33 in the back surface of the semiconductor wafer 1, the die strength of a chip can be suppressed and invasion of the contamination impurities from the back surface of semiconductor wafer 1 can be prevented simultaneously. Furthermore diffusion of the contamination impurities to the circuit formation surface of semiconductor wafer 1 can be prevented, and the characteristic defect of the semiconductor element resulting from contamination impurities can be prevented.

A second crushing layer may be formed as a modification of the 2nd method of the above, without forming insulating film 32 in the back surface of semiconductor wafer 1. That is, the back surface of semiconductor wafer 1 from which first crushing layer 5 was removed by stress relief is UV laser irradiated, and third crushing layer 33 may be formed in the back surface of semiconductor wafer 1 by the energy. Since an atomic level warp layer will be again formed in the front surface of a pure crystal layer when the back surface of semiconductor wafer 1 which stress relief finished is irradiated by the sandblasting method, as described above, this cannot prevent lowering of the die strength of a chip. Therefore, to use the sandblasting method, it is necessary to form insulating film 32 in the back surface of semiconductor wafer 1 beforehand. On the other hand, in the case of the second method, the crushing layer formed of UV laser light is strong to mechanical stress, and is a layer of higher hardness relatively. Therefore, even if insulating film 32 is not formed, it is possible to suppress lowering of chip die strength. However, when the whole surface (all the plane regions in the layer which irradiates a laser beam) is UV laser irradiated to the end portion of a chip in the state where insulating film 32 is not formed, the die strength of a chip may fall. This is because melting of the end portion of a chip is done, so the side will be distorted (it moved in a zigzag direction) and stress concentrates there. When it is on insulating film 32, the stress will become difficult to progress, but it is desirable to leave predetermined width from the periphery of a chip and to irradiate a laser beam from the reason for the above. As for the above-mentioned predetermined width, less than 500 μm is considered to be a suitable range, for example (naturally depending on other conditions, not limited to this range). Although less than 300 μm can be considered as a range suitable for mass production, it is thought that less than 100pm is still more preferred.

### Embodiment 3

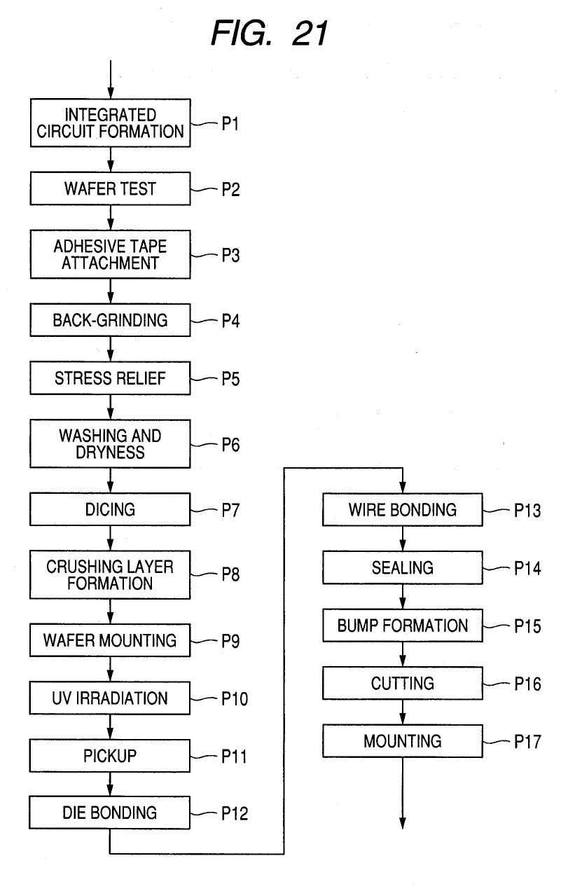

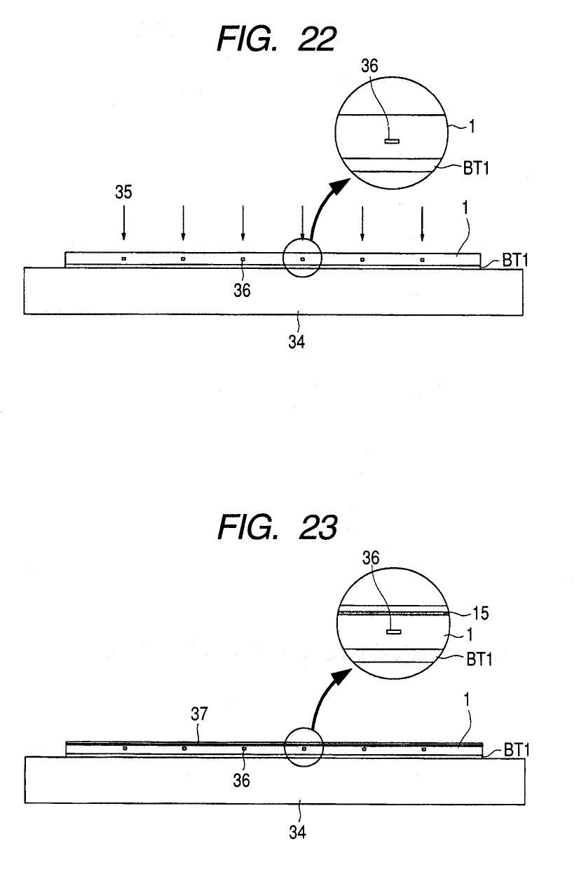

In Embodiment 3, the second crushing layer which has gettering capability is formed to the predetermined region of the predetermined depth from the back surface of semiconductor wafer 1 in a dicing step. Therefore, the step which is different from the Embodiment 1 in Embodiment 3 is a dicing step from a crush-layer-forming step. So, the same steps as the Embodiment 1, i.e., stress relief step from an integrated circuit forming step, and an assembling step from a UV irradiation step are omitted. The following explanation explains each step from a crush-layer-forming step to a dicing step. The manufacturing method of the semiconductor integrated circuit device by Embodiment 3 is explained to process order using FIG. 23 from FIG. 21. FIG. 21 is a process chart of the manufacturing method of a semiconductor integrated circuit device, and FIG. 22 and FIG. 23 are the principal part side views of the semiconductor integrated circuit device in a manufacturing process.

First, after sticking adhesive tape BT1 (first tape) on the circuit formation surface of semiconductor wafer 1, the back surface of semiconductor wafer 1 is ground. The thickness of semiconductor wafer 1 is made predetermined thickness, for example, less than 100pm less than 80 μm, or less than 60 μm (back-grinding step P4 of FIG. 21). In this back-grinding, rough grinding and finish grinding are performed one by one like the Embodiment 1.

Next, stress relief removes first crushing layer 5 (stress relief step P5 of FIG. 21), and semiconductor wafer 1 is washed and dried continuously (washing and drying step P6 of FIG. 21).

Next, as shown in FIG. 22, where adhesive tape BT1 is stuck to the circuit formation surface of semiconductor wafer 1, dicing of the semiconductor wafer 1 is done (dicing step P7 of FIG. 21). First, vacuum adsorption of the back surface of semiconductor wafer 1 is done by a wafer transport jig, and it transports to a dicing apparatus as it is, and lays on chuck table 34. Then, a scribe-line is irradiated 35 with laser and crushing layer 36 is formed vertically and horizontally along the scribe-line of semiconductor wafer 1. The depth of semiconductor wafer 1 with which laser beam 35 is irradiated is roughly half of the thickness of semiconductor wafer 1, for example. By using laser beam 35 for dicing of semiconductor wafer 1, a width of cut can be made very smaller than dicing (refer to the FIG. 8) using a disk blade. Since dicing is performed by using the back surface of semiconductor wafer 1 as the upper surface, it is necessary to form an alignment mark etc. also in the back surface of semiconductor wafer 1 beforehand.

Next, as shown in FIG. 23, in the state which laid semiconductor wafer 1 on chuck table 34 of a dicing apparatus, then, the method which is the same as that of the method explained in the Embodiment 1 is used, Second crushing layer 15 which has the gettering capability which prevents invasion of the contamination impurities from the back surface of semiconductor wafer 1 is formed in the predetermined region of the predetermined depth from the back surface of semiconductor wafer 1 (crush-layer-forming step P8 of FIG. 21). That is, in order to use infrared rays for a laser beam and to prevent lowering of the die strength of a chip, it leaves predetermined width from the periphery of a chip, and a laser beam is irradiated.

At Embodiment 3, second crushing layer 15 formed in order to prevent invasion of the contamination impurities from the back surface of semiconductor wafer 1 can be formed at the same step as dicing of semiconductor wafer 1. By these, the manufacturing method of the semiconductor integrated circuit device of Embodiment 3 has the advantage that TAT can be made shorter than the manufacturing method of the semiconductor integrated circuit device in the Embodiment 1 and Embodiment 2.

Next, semiconductor wafer 1 is again mounted on up to other tables from chuck table 34 of laser beam irradiation equipment. Then, like the Embodiment 1, the circumference of dicing tape DT1 is depressed and chip SC1 is separately divided by extending dicing tape DT1.

Then, the product shown in the FIG. 17 is completed through wafer mounting step P9, UV irradiation step P10, picking-up step P11, die-bonding step P12, etc. one by one.

In the foregoing, the present invention accomplished by the present inventors is concretely explained based on above embodiments, but the present invention is not limited by the above embodiments, but variations and modifications may be made, of course, in various ways in the limit that does not deviate from the gist of the invention.

The present invention is performed after the preceding process which forms a circuit pattern on a semiconductor wafer and tests a chip one by one, and can be applied to the back process which assembles a chip for a product.

What is claimed is:

1. A manufacturing method of a semiconductor integrated circuit device, comprising the steps of:
(a) forming a circuit pattern over a first main surface of a semiconductor wafer which has a first thickness;
(b) grinding a second main surface of the semiconductor wafer using a first abrasive which has fixed abrasive, making the semiconductor wafer a second thickness, and forming a crushing layer in a second main surface of the semiconductor wafer;
(c) removing the crushing layer of the second main surface of the semiconductor wafer;
(d) irradiating a laser beam from the second main surface side of the semiconductor wafer after the step (c), and forms a second crushing layer in a predetermined region of a predetermined depth from the second main surface of the semiconductor wafer; and
(e) doing dicing of the semiconductor wafer and individually separating the semiconductor wafer for a chip.

2. A manufacturing method of a semiconductor integrated circuit device according to claim 1, comprising a step of:
after the step (b), grinding the second main surface of the semiconductor wafer using a second abrasive which has a fixed abrasive whose particle diameter is smaller than the first abrasive, making the semiconductor wafer a third thickness, and forming the first crushing layer in the second main surface of the semiconductor wafer.

3. A manufacturing method of a semiconductor integrated circuit device according to claim 1, wherein
laser beams irradiated at the step (d) are near infrared rays.

4. A manufacturing method of a semiconductor integrated circuit device, comprising the steps of:
(a) forming a circuit pattern over a first main surface of a semiconductor wafer which has a first thickness;
(b) after sticking a first tape to the first main surface of the semiconductor wafer, grinding a second main surface of the semiconductor wafer using a first abrasive which has fixed abrasive, making the semiconductor wafer a second thickness, and forming a crushing layer in the second main surface of the semiconductor wafer;
(c) removing the crushing layer of the second main surface of the semiconductor wafer;
(d) after the step (d), irradiating laser beam in a scribe-line of the semiconductor wafer from the second main surface side of the semiconductor wafer, and doing dicing of the semiconductor wafer;
(e) after the step (d), irradiating a laser beam from the second main surface side of the semiconductor wafer, and forming a second crushing layer in a predetermined region of a predetermined depth from the second main surface of the semiconductor wafer; and
(f) individually separating the semiconductor wafer for a chip.

5. A manufacturing method of a semiconductor integrated circuit device according to claim 4, comprising a step of:
after the step (b), grinding the second main surface of the semiconductor wafer using a second abrasive which has a fixed abrasive whose particle diameter is smaller than the first abrasive, making the semiconductor wafer a third thickness, and forming the first crushing layer in the second main surface of the semiconductor wafer.

6. A manufacturing method of a semiconductor integrated circuit device according to claim 4, wherein
the step (f) includes a following subordinate step:
(f1) extending the first tape stuck to the first main surface of the semiconductor wafer, and individually separating the semiconductor wafer for a chip.

7. A manufacturing method of a semiconductor integrated circuit device according to claim 4, wherein
the laser beams irradiated from the second main surface of the semiconductor wafer at the step (f) are near infrared rays.

8. A manufacturing method of a semiconductor integrated circuit device according to claim 1, wherein
the second crushing layer is not formed in a peripheral part of the chip.

9. A manufacturing method of a semiconductor integrated circuit device according to claim 1, wherein
the second crushing layer is formed between the second main surface of the semiconductor wafer which has the third thickness and a half of the thickness of the semiconductor wafer.

10. A manufacturing method of a semiconductor integrated circuit device according to claim 1, wherein
the second crushing layer thickness is less than 1 μm.

11. A manufacturing method of a semiconductor integrated circuit device according to claim 1, wherein
the second crushing layer thickness is less than 0.5 μm.

12. A manufacturing method of a semiconductor integrated circuit device according to claim 1, wherein
the second crushing layer thickness is less than 0.1 μm.

13. A manufacturing method of a semiconductor integrated circuit device according to claim 1, wherein
a third thickness of the semiconductor wafer is less than 100 μm.

14. A manufacturing method of a semiconductor integrated circuit device according to claim 1, wherein
a third thickness of the semiconductor wafer is less than 80 μm.

15. A manufacturing method of a semiconductor integrated circuit device according to claim 1, wherein
a third thickness of the semiconductor wafer is less than 60 μm.

16. A manufacturing method of a semiconductor integrated circuit device, comprising the steps of:
(a) forming a circuit pattern over a first main surface of a semiconductor wafer which has a first thickness;
(b) grinding a second main surface of the semiconductor wafer using a first abrasive which has fixed abrasive, making the semiconductor wafer a second thickness, and forming a crushing layer in the second main surface of the semiconductor wafer;
(c) removing the crushing layer of the second main surface of the semiconductor wafer;
(d) after the step (c), forming an insulating film of a thickness of less than 0.1 μm in the second main surface of the semiconductor wafer;
(e) forming a third crushing layer in a front surface of the insulating film; and
(f) doing dicing of the semiconductor wafer and individually separating the semiconductor wafer for a chip.

17. A manufacturing method of a semiconductor integrated circuit device according to claim 16, comprising a step of:
after the step (b), grinding the second main surface of the semiconductor wafer using a second abrasive which has a fixed abrasive whose particle diameter is smaller than the first abrasive, making the semiconductor wafer a third thickness, and forming the first crushing layer in the second main surface of the semiconductor wafer.

18. A manufacturing method of a semiconductor integrated circuit device according to claim 16, wherein
the step (e) includes a following subordinate step:
(e1) injecting an abrasive particle over a front surface of the insulating film, and forming the third crushing layer in a front surface of the insulating film.

19. A manufacturing method of a semiconductor integrated circuit device according to claim 16, wherein
the step (f) includes a following subordinate step:
(f1) irradiating laser beams in a front surface of the insulating film and forming the third crushing layer in a front surface of the insulating film.

20. A manufacturing method of a semiconductor integrated circuit device according to claim 16, wherein
the third crushing layer thickness is less than 0.05 μm.

21. A manufacturing method of a semiconductor integrated circuit device according to claim 16, wherein
the third crushing layer thickness is less than 0.03 μm.

22. A manufacturing method of a semiconductor integrated circuit device according to claim 16, wherein
the third crushing layer thickness is less than 0.01 μm.
